(19) United States
(12) Patent Application Publication
(10) Pub. No.: US 2009/0251185 A1
(43) Pub. Date: Oct. 8, 2009

(54) DATA RETENTION DEVICE FOR MULTIPLE POWER DOMAINS

(75) Inventors: JENG-HUANG WU, Hsinchu (TW); CHIH-WEN YANG, Hsinchu (TW)

Correspondence Address: WPAT, PC, 7225 BEVERLY ST., ANNANDALE, VA, 22003, US

(73) Assignee: FARADAY TECHNOLOGY CORPORATION, Hsinchu (TW)

(21) Appl. No.: 12/416,380

(22) Filed: Apr. 1, 2009

(30) Foreign Application Priority Data
Apr. 3, 2008 (TW) 097112248

(51) Int. Cl. H03K 3/289

(52) U.S. Cl. 327/202

(57) ABSTRACT

A data retention device includes a first latch disposed between a data input terminal and a data output terminal for storing a data signal received from the data input terminal and transmitting the data signal through a data forward path to the data output terminal according to a clock signal in an operational mode; a second latch disposed in a branch of the data forward path between the first latch and the data output terminal for receiving the data signal in the operational mode and retaining the data signal in a sleep mode; and a first tri-state buffer disposed in the data forward path between the first latch and the branched second latch and enabled to conduct the data forward path in the operational mode and disabled to cut off the data forward path in the sleep mode according to a data retention signal.

### FIELD OF THE INVENTION

The present invention relates to a data retention device, and more particularly to a data retention device for multiple power domains.

### BACKGROUND OF THE INVENTION

Multiple power domains are commonly adopted by many semiconductor integrated logic devices. In an operational mode, all the power domains are supplied with normal power to keep a semiconductor integrated logic device work. On the other hand, in a sleep mode, only partial power domains are supplied with power for retaining data and settings required for recovering the semiconductor integrated logic device from the sleep mode to the operational mode while the other power domains are suspended from power supply in order to save power.

For retaining data and settings in the sleep mode, a data retention device for multiple power domains is developed. As disclosed in U.S. Pat. No. 7,180,348 and as illustrated in FIG. 1, a conventional data retention device is implemented with a master-slave flip-flop, which includes a tristateable device 30, a master latch 10, a tristateable device 32 and a slave latch 20. The tristateable device 30 and the tristateable device 32 are implemented with transmission gates.

It is shown in FIG. 1 that a clock signal “clk” and a sleep signal “/sleep” are inputted to a NAND gate to obtain an output clock signal “nclk”. The clock signal “nclk” is then inputted to a NOT gate to output a complementary clock signal “bclk”. Furthermore, with a data signal “D” coupled to an input end of the tristateable device 30 and the master latch 10 coupled to an output end of the tristateable device 30, the data signal inputted into the tristateable device 30 is inverted into a data signal “/D” by the master latch 10. The inverted data signal “/D” is then inputted into the tristateable device 32, which has an output end coupled to the slave latch 20, and then recovered to the data signal D and outputted from an output terminal Q by the slave latch 20. In other words, the path from the input end of the tristateable device 30 through the master latch 10, the tristateable device 32 and the slave latch 20 to the output terminal Q forms a data forward path. Furthermore, while the conduction between the master latch 10 and two power sources Vdd and Vss is controlled by a switch element, e.g. a power transistor 40, the slave latch 20 is directly connected to the two power sources Vdd and Vss.

In the operational mode, the sleep signal “/sleep” is at a high level. When the clock signal “nclk” is at a high level but the clock signal “bclk” is at a low level, the tristateable device 30 is enabled to have the data signal D transmitted to the master latch 10. Meanwhile, the tristateable device 32 is disabled to block the inverted data signal “/D” from entering the slave latch 20. On the other hand, when the clock signal “nclk” is at a low level but the clock signal “bclk” is at a high level, the tristateable device 30 is disabled to block the data signal “D” from entering the master latch 10, while the tristateable device 32 is enabled to have the inverted data signal “/D” transmitted to the slave latch 20.

In the sleep mode, the sleep signal “/sleep” is at a low level. Meanwhile, the switch element 40 is open (off) so as to stop conducting the master latch 10 with the two voltage sources Vdd and Vss. Accordingly, the data stored in the master latch 10 will be lost. Nevertheless, by keeping the clock signal “nclk” at the high level and keeping the clock signal “bclk” at the low level, the tristateable device 32 is disabled so as to isolate the slave latch 20 from the master latch 10. As a result, the data stored in the slave latch 20 can be retained.

Please refer to FIG. 2, in which another conventional data retention device as disclosed in US Patent Publication No. 2007/0085585 and US Patent Publication No. 2007/0103217 is illustrated. The data retention device is also implemented with a master-slave flip-flop, which includes a NOT gate 230, a tristateable device 232, a master latch 210, a tristateable device 234 and a NOT gate 236 connected between an input terminal D and an output terminal Q in series, and a tristateable device 250 and a slave latch 220 connected between the tristateable device 234 and NOT gate 236 as a branch. In other words, the path from the input terminal D through the NOT gate 230, tristateable device 232, master latch 210, tristateable device 234 and NOT gate 236 to the output terminal Q forms a data forward path. The tristateable device 250 and slave latch 220 are not in the data forward path. The tristateable devices 232, 234 and 250 are implemented with transmission gates.

In a clock path 212 of FIG. 2, a clock signal “clk” is inputted into a NOT gate to be converted into a clock signal “nclk”. The clock signal “nclk” is then inputted to another NOT gate to be converted into a clock signal “bclk”. The clock signals “nclk” and “bclk” are complementary to each other. On the other hand, in a data retention signal path 214, a data retention signal “ret” is inputted into a NOT gate to obtain an inverted data retention signal “nret” that is complementary to the data retention signal “ret”. The tristateable devices 232 and 234 are controlled by the clock signals “nclk” and “bclk” while the tristateable device 236 is controlled by data retention signal “ret” and the inverted data retention signal “nret”.

The operational mode is indicated when the data retention signal “ret” is at a low level, while the sleep mode is indicated when the data retention signal “ret” is at a high level.

In the sleep mode, since the data retention signal “ret” is at the high level, the tristateable device 250 is disabled so as to isolate the slave latch 220 from the data forward path. On the other hand, the tristateable device 250 is enabled in the operational mode so as to have the slave latch 220 conducted with the data forward path for transmitting data from the slave latch 220 to the output terminal Q.

The shaded portions in FIG. 2 represent the partial circuitry where power is still supplied in the sleep mode. It includes the slave latch 220, tristateable device 250, elements in the clock path 212 and elements in the data retention signal path 214.

FIG. 3 illustrates a further convention data retention device as disclosed in US Patent Publication No. 2007/0085585 and US Patent Publication No. 2007/0103217. The data retention device is also implemented with a master-slave flip-flop, which includes a NOT gate 330, a tristateable device 332, a master latch 310, a tristateable device 334 and a NOT gate 336 connected between an input terminal D and an output terminal Q in series, and a tristateable device 350 and a slave latch 320 connected between the tristateable device 334 and NOT gate 336 as a branch. In other words, the path from the input terminal D through the NOT gate 330, tristateable device 332, master latch 310, tristateable device 334 and NOT gate 336 to the output terminal Q forms a data forward path. The tristateable device 350 and slave latch 320 are not in the data forward path. The tristateable devices 332, 334 and 350 are implemented with transmission gates.

The device shown in FIG. 3 differs from that shown in FIG. 2 in the configuration of the slave latch 320. By using such a slave latch 320, the elements in the clock path 312 need not be powered while the slave latch 320 is capable of storing data in the sleep mode. Therefore, the power-saving effect is improved.

The shaded portions in FIG. 3 represent the partial circuitry where power is still supplied in the sleep mode. It includes the slave latch 320, tristateable device 350 and elements in the data retention signal path 314.

### SUMMARY OF THE INVENTION

An objective of the present invention is to provide a data retention device with different architecture from the conventional data retention devices and improved properties.

For achieving the object, the present invention provides a data retention device which includes a first latch disposed between a data input terminal and a data output terminal for storing a data signal received from the data input terminal and transmitting the data signal through a data forward path to the data output terminal according to a clock signal in an operational mode; a second latch disposed in a branch of the data forward path between the first latch and the data output terminal for receiving the data signal in the operational mode and retaining the data signal in a sleep mode; and a first tri-state buffer disposed in the data forward path between the first latch and the branched second latch and enabled to conduct the data forward path in the operational mode and disabled to cut off the data forward path in the sleep mode according to a data retention signal.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic circuit diagram illustrating a convention data retention device;

FIG. 2 is a schematic circuit diagram illustrating another convention data retention device;

FIG. 3 is a schematic circuit diagram illustrating a further convention data retention device;

FIG. 4A is a functional block diagram schematically illustrating a data retention device according to an embodiment of the present invention;

FIG. 4B is a circuit diagram illustrating embodiments of the tri-state buffers used in the data retention device of FIG. 4A;

FIG. 4C is a circuit diagram illustrating other embodiments of the tri-state buffers used in the data retention device of FIG. 4A;

FIG. 5A is a functional block diagram schematically illustrating a data retention device according to another embodiment of the present invention;

FIG. 5B is a circuit diagram illustrating embodiments of the tri-state buffers used in the data retention device of FIG. 5A; and

FIG. 5C is a circuit diagram illustrating other embodiments of the tri-state buffers used in the data retention device of FIG. 5A.

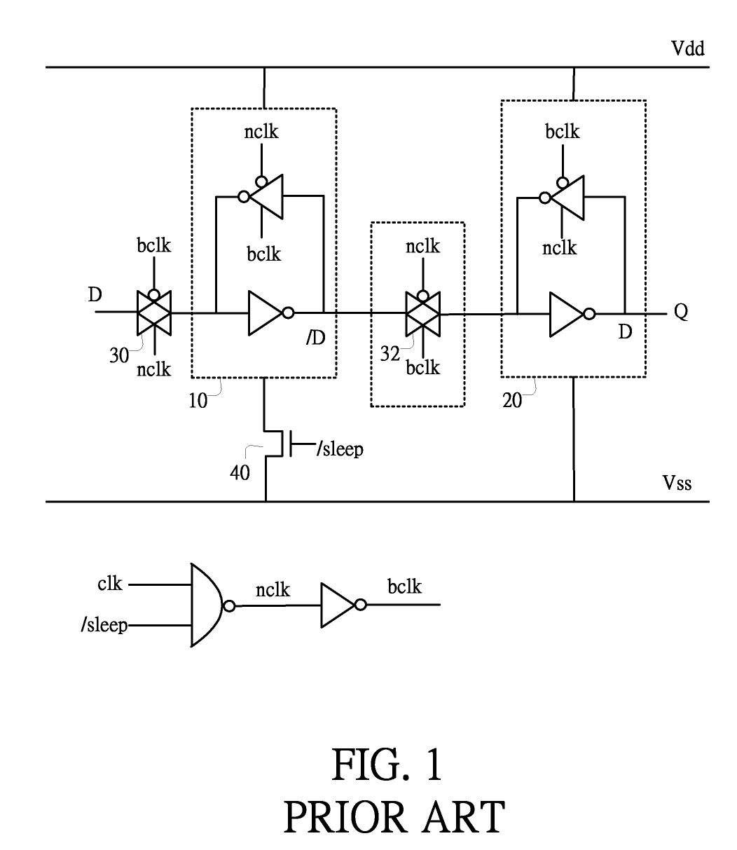

### DETAILED DESCRIPTION OF THE PREFERRED EMBODIMENT

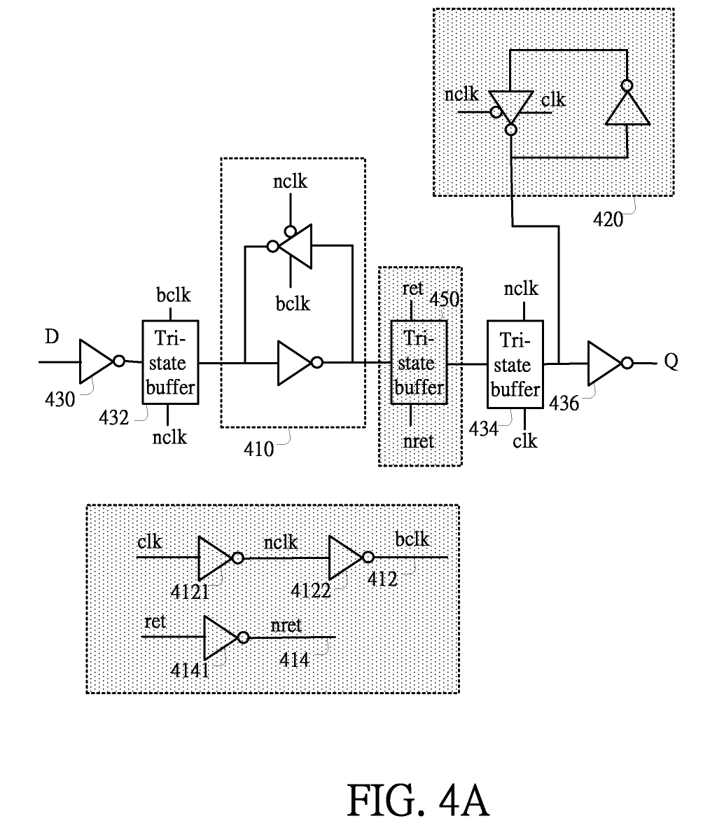

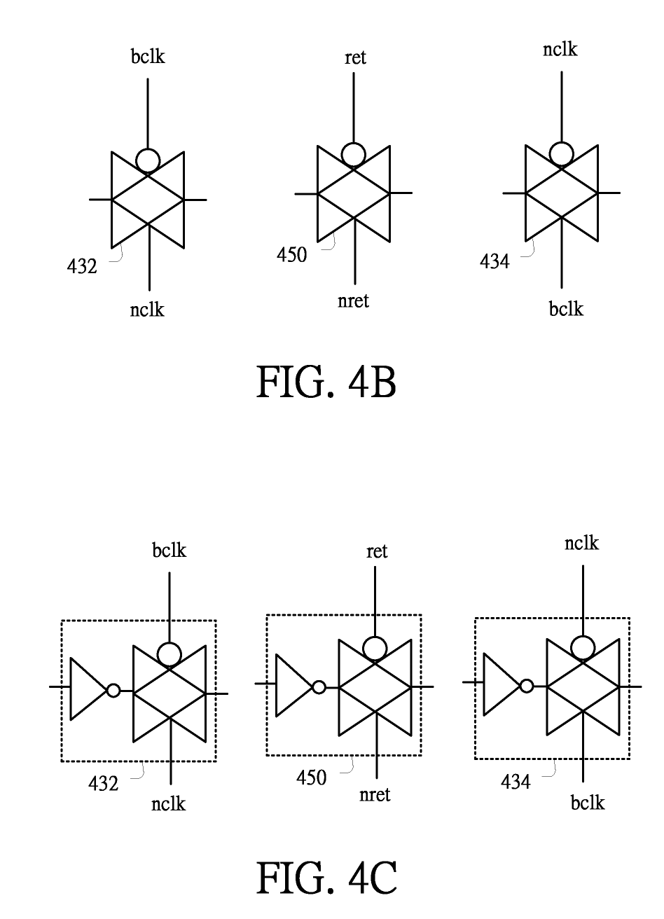

A data retention device according to an embodiment of the present invention is illustrated in FIG. 4A, which is implemented with a master-slave flip-flop and includes a NOT gate 430, a tri-state buffer 432, a master latch 410, a tri-state buffer 450, a tri-state buffer 434 and a NOT gate 436 connected between an input terminal D and an output terminal Q in series, and a slave latch 420 connected between the tri-state buffer 434 and the NOT gate 436 as a branch.

The data retention device works in response to clock signals “nclk” and “bclk” which are provided by a clock path 412 in response to a reference clock signal “clk”. The reference clock signal “clk” is inputted into a NOT gate 4121 to obtain the clock signal “nclk”. The clock signal “nclk” is then inputted into another NOT gate 4122 to obtain the clock signal “bclk”, which is complementary to the clock signal “nclk”. The tri-state buffers 432 and 434 are controlled by the clock signals “nclk” and “bclk”.

On the other hand, the data retention device further works in response to a data retention signal “ret” and an inverted data retention signal “nret” which are provided by a data retention signal path 414. The data retention signal “ret” is inputted into a NOT gate 4141 to obtain the inverted data retention signal “nret”, which is complementary to the data retention signal “ret”. The tri-state buffer 450 is controlled by the data retention signal “ret” and the inverted data retention signal “nret”.

A low level of the data retention signal “ret” indicates an operational mode while a high level of the data retention signal “ret” indicates a sleep mode.

In this embodiment, the path from the input terminal D through the NOT gate 430, tri-state buffer 432, master latch 410, tri-state buffer 450, tri-state buffer 434 and NOT gate 436 to the output terminal Q forms a data forward path. The slave latch 420 is not in the data forward path.

In the operational mode, e.g. the data retention signal “ret” is in the low level, the tri-state buffer 450 is kept enabled so that data can be transmitted through the data forward path section by section with the high/low changes of the clock signals “nclk” and “bclk”. For example, when the clock signal “nclk” is at a high level but the clock signal “bclk” is at a low level, the tri-state buffer 432 is enabled to have the data signal inputted from the input terminal D transmitted to the master latch 410. Meanwhile, the tri-state buffer 434 is disabled to block the inverted data signal from entering the slave latch 420. On the other hand, when the clock signal “nclk” is at a low level but the clock signal “bclk” is at a high level, the tri-state buffer 432 is disabled to block the data signal from entering the master latch 410, while the tri-state buffer 434 is enabled such that the data signal kept in the master latch 410 can be transmitted to the slave latch 420.

In the sleep mode, e.g. the data retention signal “ret” is in the high level, the tri-state buffer 450 is disabled so as to cut off the data forward path. Meanwhile, power is continuously supplied to the slave latch 420 for retaining data stored in the slave latch 420.

In addition to the slave latch 420, power is also supplied to the tri-state buffer 450, elements in the clock path 412 and elements in the data retention signal path 414, as indicated by the shaded portions in FIG. 4A.

Please refer to FIG. 4B which illustrates circuit diagrams of embodiments of the three tri-state buffers 432, 434 and 450. The three tri-state buffers 432, 434 and 450 are implemented with transmission gates.

Please refer to FIG. 4C which illustrates circuit diagrams of other embodiments of the three tri-state buffers 432, 434 and 450. Each of the three tri-state buffers 432, 434 and 450 includes a logic gate, e.g. a NOT gate, and a transmission gate connected in series.

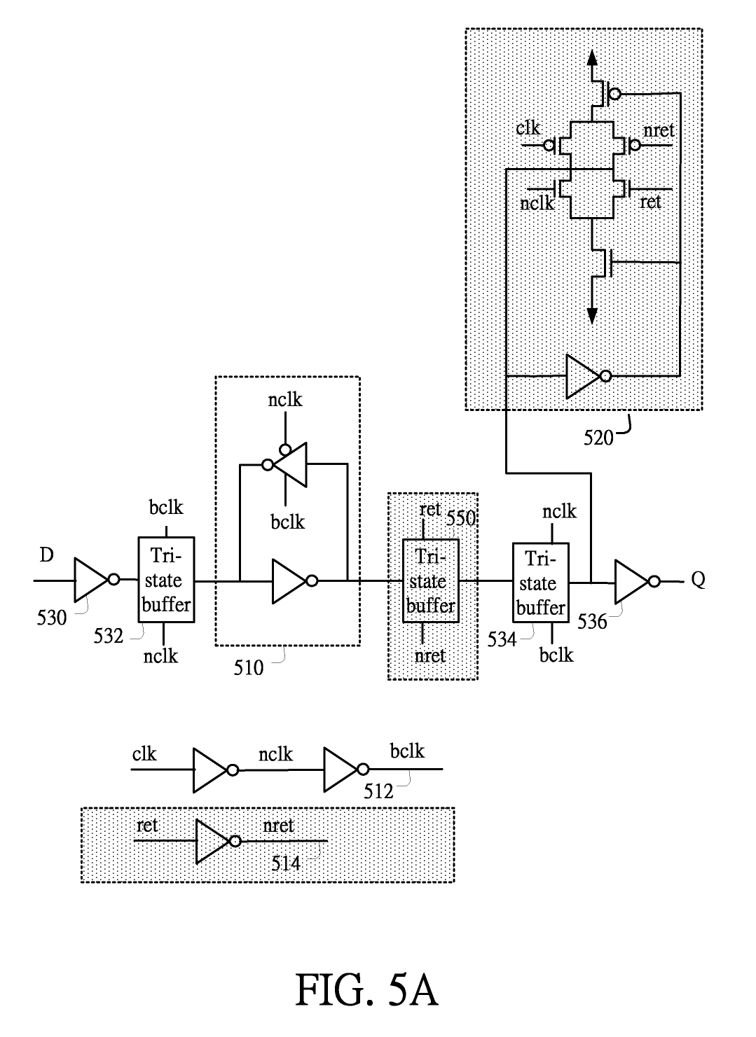

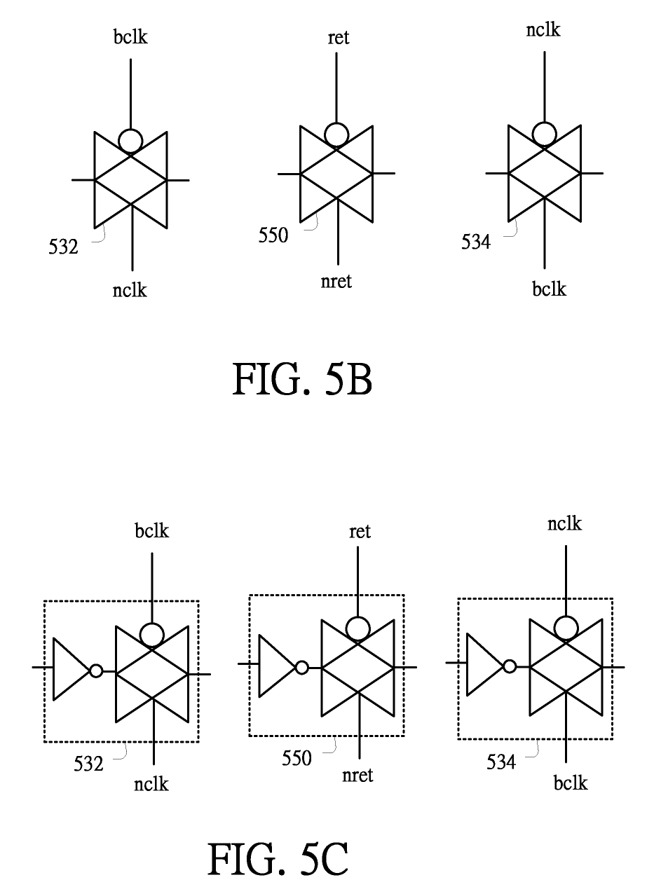

Please refer to FIG. 5A, which illustrates a data retention device according to another embodiment of the present invention. Likewise, the data retention device is implemented with a master-slave flip-flop and includes a NOT gate 530, a tri-state buffer 532, a master latch 510, a tri-state buffer 550, a tri-state buffer 534 and a NOT gate 536 connected between an input terminal D and an output terminal Q in series, and a slave latch 520 connected between the tri-state buffer 534 and the NOT gate 536 as a branch. The path from the input terminal D through the NOT gate 530, tri-state buffer 532, master latch 510, tri-state buffer 550, tri-state buffer 534 and NOT gate 536 to the output terminal Q forms a data forward path. The slave latch 520 is not in the data forward path.

The device shown in FIG. 5A differs from that shown in FIG. 4A in the configuration of the slave latch 520. By using such a slave latch 520, the elements in the clock path 512 need not be powered while the slave latch 520 is capable of storing data in the sleep mode. Therefore, the power-saving effect is improved.

The shaded portions in FIG. 5A represent the partial circuitry where power is still supplied in the sleep mode. It includes the slave latch 520, tristateable device 550 and elements in the data retention signal path 514.

Please refer to FIG. 5B which illustrates circuit diagrams of embodiments of the three tri-state buffers 532, 534 and 550. The three tri-state buffers 532, 534 and 550 are implemented with transmission gates.

Please refer to FIG. 5C which illustrates circuit diagrams of other embodiments of the three tri-state buffers 532, 534 and 550. Each of the three tri-state buffers 532, 534 and 550 includes a logic gate, e.g. a NOT gate, and a transmission gate connected in series.

It can be understood from the above embodiments that a data retention device according to the present invention, compared to the prior art, includes a tri-state buffer controlled by a data retention signal and an inverted data retention signal lying in the data forward path. The tri-state buffer is enabled in an operational mode while being disabled in a sleep mode. The present invention further includes a slave latch staying as a branch and supplied with power in both the operational mode and sleep mode for retaining data.

Furthermore, the data retention device according to the present invention is advantageous over the prior art in timing control and timing constraint realization.

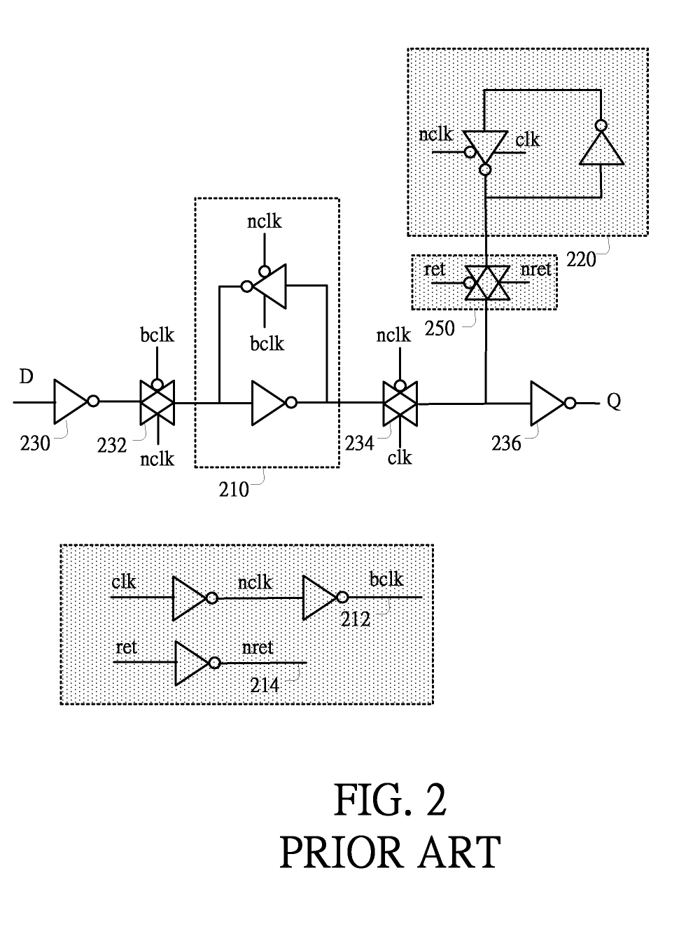

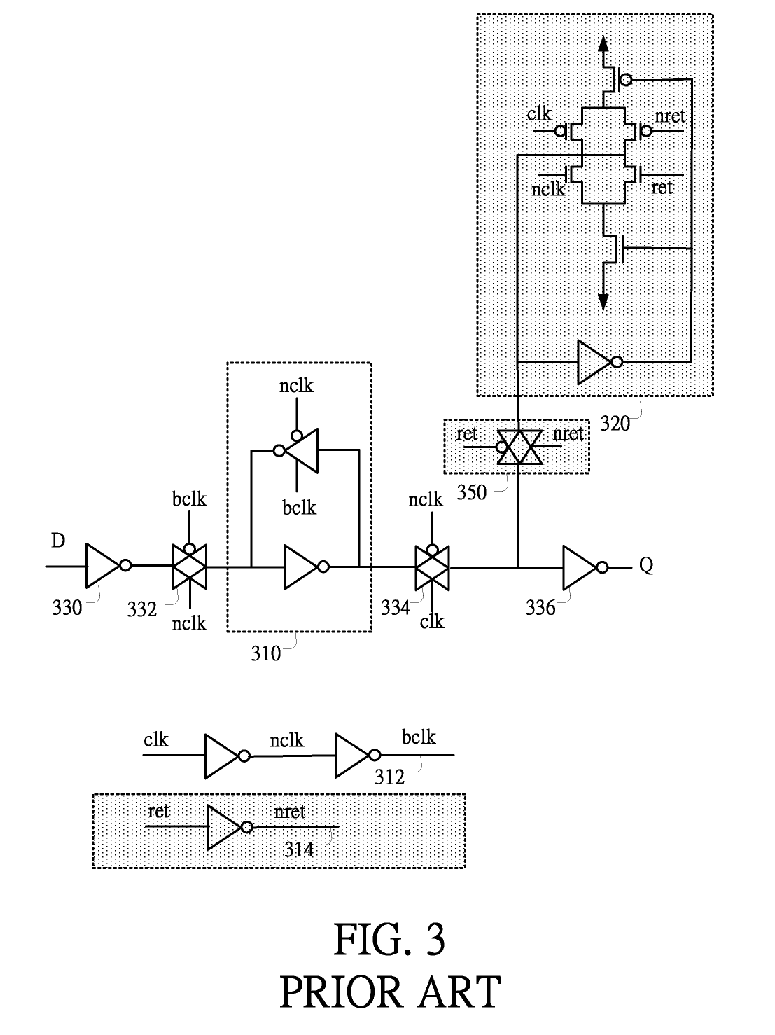

Generally, a data retention device usually works with other circuitry such as an isolation cell for avoiding data error while switching between sleep and operational modes. For example, the isolation cell is coupled to the output terminal Q of the data retention device, and receives data from the output terminal Q in response to the control/triggering of an isolation control signal. Therefore, the conventional data retention devices as illustrated in FIG. 2 and FIG. 3 requires an additional isolation control signal for such a purpose. The isolation control signal is inherently of an appropriate delay from the data retention signal “ret” because the data retention signal “ret” has to enable the tristateable device 250/350 first before the retained data in the slave latch 220/230 in the same branch can be transmitted to the data forward path to be outputted from the output terminal Q. That is, an additional delayed isolation control signal is required for the isolation cell coupled to the output terminal Q to correctly receive the data from the slave latch 220/230. The additional isolation control signal complicates the timing control of the system.

In contrast, the data retention device according to the present invention may use the data retention signal “ret” itself or other synchronous signals as the isolation control signal for controlling the data transmission to the isolation cell coupled to the output terminal Q. Since the tri-state buffer 450/550 controlled by the data retention signal and the inverted data retention signal is in the data forward path, the retained data in the slave latch 420/520 can be transmitted to the isolation cell in response to the data retention signal “ret” directly when the system is recovered from the sleep mode to the operational mode. Accordingly, the timing control for switching between the operational and sleep modes according to the present invention is simplified and the cost is reduced compared to the prior art.

Furthermore, as understood by those skilled in IC designs, definite timing constraint is an important factor for verifying placing and routing of an IC design. For data retention, definite timing constraint assures of proper operational timing control of the data retention device by well defining timing correlations among clock signals, data retention signals and data signals.

For the conventional data retention devices as illustrated in FIG. 2 and FIG. 3, timing constraint cannot be well define because cell characterization is hard to be achieved. Take the data retention device as illustrated in FIG. 2 for example. Since the two tristateable devices 234 and 250 respectively control two split data paths, the timing correlation of the clock signal “clk” to the data retention signal “ret” is indefinite. Accordingly, it is hard and impractical to acquire definite timing constraint according to the prior art, and thus the circuitry design, circuitry verification and circuitry implementation will be adversely affected.

In contrast, the present invention is able to practically and clearly define timing constraint according to circuit features, e.g. driving capability of a transistor. Since the tri-state buffers are disposed in the same data path according to the present invention, cell characterization is possible and definite timing constraint, e.g. timing correlation of the clock signal “clk” to the data retention signal “ret”, can be realized. Accordingly, it is feasible to practice circuitry design, circuitry verification and circuitry implementation based on the definite timing constraint.

While the invention has been described in terms of what is presently considered to be the most practical and preferred embodiments, it is to be understood that the invention needs not to be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A data retention device, comprising:
a first latch disposed between a data input terminal and a data output terminal for storing a data signal received from the data input terminal and transmitting the data signal through a data forward path to the data output terminal according to a clock signal in an operational mode;
a second latch disposed in a branch of the data forward path between the first latch and the data output terminal for receiving the data signal in the operational mode and retaining the data signal in a sleep mode; and
a first tri-state buffer disposed in the data forward path between the first latch and the branched second latch and enabled to conduct the data forward path in the operational mode and disabled to cut off the data forward path in the sleep mode according to a data retention signal.

2. The data retention device according to claim 1 wherein the first latch is a master latch and the second latch is a slave latch.

3. The data retention device according to claim 1 wherein the first tri-state buffer includes a transmission gate.

4. The data retention device according to claim 1 wherein the first tri-state buffer includes a logic gate and a transmission gate connected in series.

5. The data retention device according to claim 4 wherein the logic gate is a NOT gate.

6. The data retention device according to claim 1, further comprising a second tri-state buffer disposed in the data forward path between the data input terminal and the first latch.

7. The data retention device according to claim 6, further comprising a third tri-state buffer disposed in the data forward path between the first tri-state buffer and the branched second latch.

8. The data retention device according to claim 7 wherein each of the second tri-state buffer and the third tri-state buffer includes a transmission gate.

9. The data retention device according to claim 7 wherein each of the second tri-state buffer and the third tri-state buffer includes a logic gate and a transmission gate connected in series.

10. The data retention device according to claim 9 wherein the logic gate is a NOT gate.

11. The data retention device according to claim 7 wherein the second tri-state buffer and the third tri-state buffer are enabled and disabled according to the clock signal.
